(19) United States
(12) Patent Application Publication
(10) Pub. No.: US 2005/0069818 A1
(43) Pub. Date: Mar. 31, 2005

(54) Absorptive resists in an extreme ultraviolet (EUV) imaging layer

(76) Inventors: Robert Bristol, Portland, OR (US); Heidi Cao, Portland, OR (US); Robert Meagley, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/676,411

(22) Filed: Sep. 30, 2003

(51) Int. Cl. G03F 7/00

(52) U.S. Cl. 430/322; 430/296

(57) ABSTRACT

An embodiment of the present invention includes a technique to provide a highly absorptive resist. A resist is formed using a highly absorbing material. The resist is thinned to a pre-determined thickness used as an imaging layer. The efficiency of a photoactive acid generator (PAG) is improved to capture secondary electrons produced by an ionizing radiation in the resist.

### BACKGROUND

1. Field of the Invention

Embodiments of the invention relates to the field of semiconductor, and more specifically, to lithography.

2. Description of Related Art

Extreme ultraviolet lithography (EUVL) is a new generation lithography that uses extreme ultraviolet (EUV) radiation with a wavelength in the range of 10 to 14 nanometer (nm) to carry out projection imaging. The EUVL system uses reflective optics and masks in which the image is formed in an absorbing photoresist.

Line edge roughness (LER) and photospeed, or sensitivity, of photoresist in lithographic processing are two important performance parameters in EUVL systems. These two parameters, however, tend to be mutually exclusive. Existing techniques to vary sensitivity and LER include changing the types and concentrations of the photoacid generators (PAGs), base quenchers, and polymers. These techniques are typically inadequate because they result in a tradeoff between sensitivity and LER.

### BRIEF DESCRIPTION OF THE DRAWINGS

The invention may best be understood by referring to the following description and accompanying drawings that are used to illustrate embodiments of the invention. In the drawings:

FIG. 1 is a diagram illustrating a device according to one embodiment of the invention.

FIG. 2 is a diagram illustrating a process to provide a resist according to one embodiment of the invention.

FIG. 3 is a diagram illustrating interactions between PAG and other resist components according to one embodiment of the invention.

FIG. 4A is a diagram illustrating a chemical structure of fluoropolymer used for resist material according to one embodiment of the invention.

FIG. 4B is a diagram illustrating a chemical structure of metallocene polymer used for resist material according to one embodiment of the invention.

FIG. 4C is a diagram illustrating a chemical structure of alkoxide chelate used for resist material according to one embodiment of the invention.

FIG. 4D is a diagram illustrating a chemical structure of carboxylate chelate used for resist material according to one embodiment of the invention.

### DESCRIPTION

An embodiment of the present invention includes a technique to increase the sensitivity of the resist by increasing sensitivity. A resist is formed using a highly absorbing material. The resist is thinned to a pre-determined thickness and used as an imaging layer. Further improvements in sensitivity occur if the efficiency of a photoactive acid generator (PAG) is improved to capture secondary electrons that are produced by an ionizing radiation in the resist.

In the following description, numerous specific details are set forth. However, it is understood that embodiments of the invention may be practiced without these specific details. In other instances, well-known circuits, structures, and techniques have not been shown in order not to obscure the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

One embodiment of the invention is a technique for using highly absorptive resist formulations in an ultra-thin imaging layer. Due to the increase in the density of secondary electrons produced by the ionizing radiation (e.g., EUV) in the resist, the dose required to exposed the photoresist is decreased. By increasing the effective energy available to expose the resist, sensitivity may be increased without the increase in LER that is typically seen for increases in sensitivity. Elements of one embodiment of the invention include: (1) Chemically amplified photo-resists (CAR) incorporating EUV-absorbing moieties, such as fluorine (F) or tin (Sn); (2) Application to CAR of moieties ionized by EUV to produce efficient electron emission; and (3) Distribution of moieties within CAR to facilitate uniform image formation with high sensitivity.

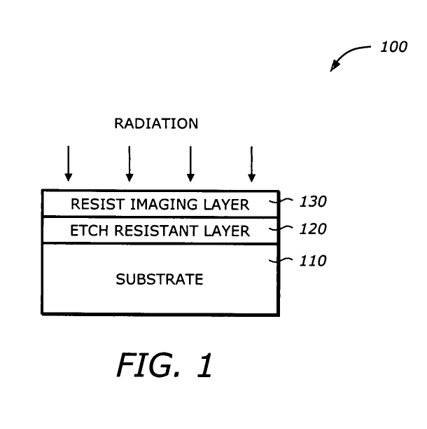

FIG. 1 is a diagram illustrating a device 100 according to one embodiment of the invention. The device 100 includes a substrate 110, an etch resistant layer 120, and an imaging layer 130.

The substrate 110 is the layer to be patterned. The etch resistant layer 120 provides a barrier to resist etching to allow pattern transfer from the imaging layer 130 to the substrate layer 110.

The imaging layer 130 is a thin layer of photoresist which includes a highly absorbing material. The imaging layer 130 is thinned to a pre-determined thickness to achieve sufficient transparency to the exposing radiation, such as EUV, X-ray, electron beam, and ion beam. Typically the thickness is below 100 nm (e.g., 60 nm). Since the imaging layer 130 is made of highly absorbing material, the overall dosage for exposure may be reduced to provide the same absorbance as one with higher thickness (e.g., 120 nm). The thickness and absorption is balanced to keep the overall transmission to approximately 50% in order to print features with good sidewall angles.

The imaging layer 130 includes a baseline material such as polyhydroxystyrene, to which is added a highly absorbing material. The highly absorbing material may be one of fluorine (F), tin (Sn), bismuth (Bi), cesium (Cs), and antimony (Sb). Other materials include a fluoropolymer, a metallocence polymer, an alkoxide chelate polymer, and a carboxylate chelate polymer. In addition, the imaging layer 130 may have an increased Photo Acid Generator (PAG) concentration. It may also have controlled moieties proximal to a cleavable bond in the PAG.

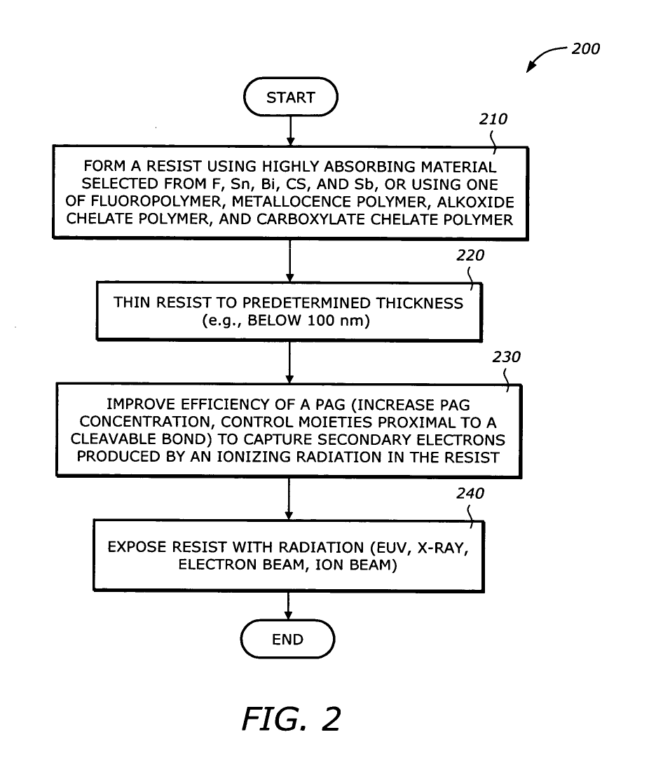

FIG. 2 is a diagram illustrating a process 200 to provide a resist according to one embodiment of the invention.

Upon START, the process 200 forms a resist using highly absorbing material selected from fluorine (F), tin (Sn), bismuth (Bi), cesium (Cs), and antimony (Sb), or using one of fluoropolymer, a metallocence polymer, an alkoxide chelate polymer, and a carboxylate chelate polymer (Block 210). This can be performed by adding a percentage in volume of the absorbing material to the baseline resist material. This percentage may range from 10% to 20%.

Next, the process 200 thins the resist to a pre-determined thickness suitable for exposure to radiation (Block 220). The thickness is typically below 100 nm (e.g., 60 nm). Reducing the film thickness is necessary for materials with high absorbance, because an increase in absorbance reduces the dose uniformity in a photoresist (i.e., the dose at the top of the photoresist film is much larger than the dose at the bottom of the photoresist film). The use of high absorbance materials for thick photoresist films can have a negative impact, such as sloped sidewall profiles. In order for high absorbance materials to be practical for lithography, the film thickness is reduced significantly.

Then, the process 200 improves the efficiency of a PAG to capture the secondary electrons produced by an ionizing radiation in the resist (Block 230), for example by placing groups with absorbance that will generate more secondary electrons in close proximity to the PAG.

Next, the process 200 exposes the resist with radiation at a wavelength (Block 240). The radiation may be one of EUV, X-ray, electron beam, and ion beam. The process 200 is then terminated.

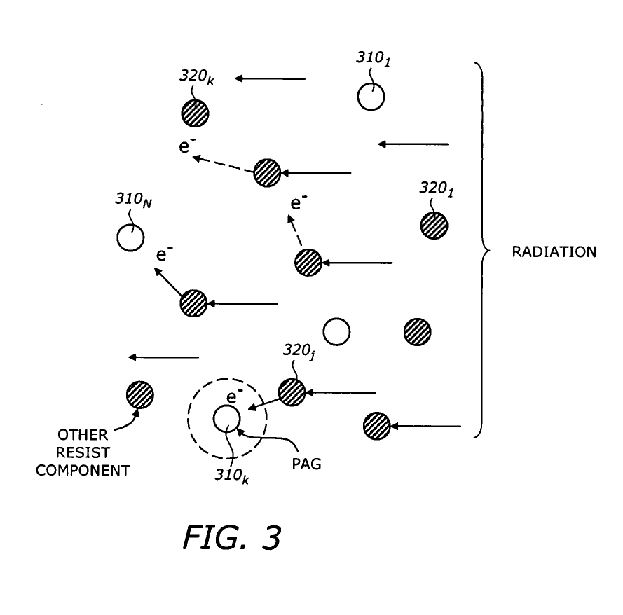

FIG. 3 is a diagram illustrating interactions between PAG and other resist components according to one embodiment of the invention. The interactions involve PAGs 310₁ to 310_{N} and other resist components 320₁ to 320_{M}.

Ionizing radiation such as EUV, X-ray and e-beam generates secondary electrons as a result from interactions (e.g., atomic excitation and ionization) with matter. The PAGs 310₁ to 310_{N} essentially capture these secondary electrons and decompose to produce acid. For example, PAG 310ₖ reacts with the electron generated by the resist component 320ⱼ to produce acid. Since any of the atoms in the resist can be ionized to produce an electron, increasing the absorption of the resist increases the probability of photon capture, leading to an increased number of secondary electrons. Therefore, the same number of electrons can be generated with a lower exposure dosage while maintaining the basic chemistry of the resist and thus avoiding problems with solubility, side lobe margin, LER, etc. Note that for traditional lithographic wavelengths, such as 248 nm and 193 nm, acid is generated by a photolysis process and increasing absorbance has no direct effect on sensitivity.

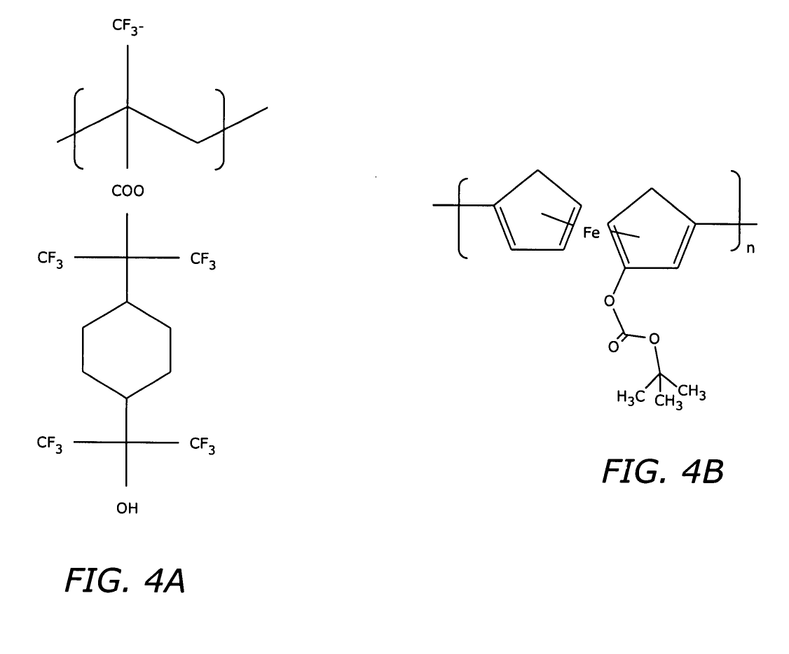

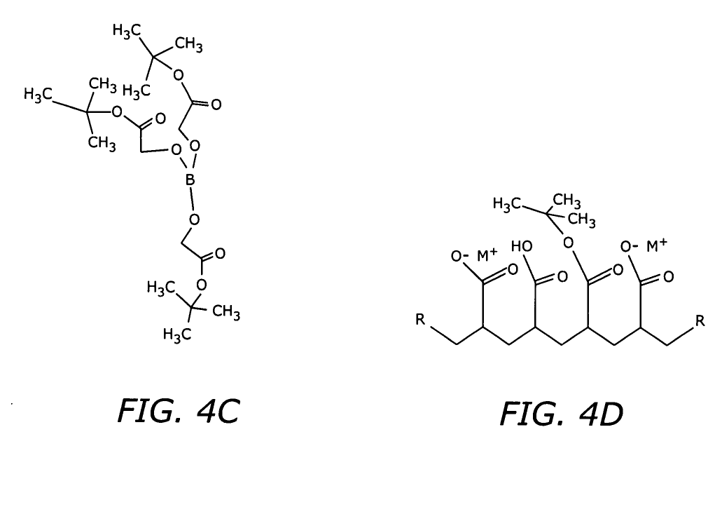

FIG. 4A is a diagram illustrating a chemical structure of a fluoropolymer used for resist material according to one embodiment of the invention. Fluorine is particularly absorbent in EUV. Its mass absorption factor is about 5.6 times that of Carbon (C). It has been shown that the absorbance of the fluoropolymer shown in FIG. 4A for a 60 nm film is about 43%, or twice that of the base line resist, polyhydroxystyrene (PHST) at 22%.

FIG. 4B is a diagram illustrating a chemical structure of a metallocene polymer used for resist material according to one embodiment of the invention. In this exemplary structure, iron is shown as a metal. Many other metals may also be suitable. This motif is directly analogous to PHST, with metal-sandwich complex taking the place of the benzene rings in Deep UltraViolet (DUV) type resist platforms.

FIG. 4C is a diagram illustrating a chemical structure of a alkoxide chelate used for resist material according to one embodiment of the invention. In this exemplary structure, borate is used. In this structure, chelation through alkoxide complexes results in metal bound to acid sensitive matrix. Oligomeric and polymeric materials may be employed. To control grain size, a lower oligomeric (trimer) complex is shown.

FIG. 4D is a diagram illustrating a chemical structure of a carboxylate chelate used for resist material according to one embodiment of the invention. The complexes may be oligomeric or polymeric. For fine grain sizes, ligands may be low in molecular weight. FIG. 4D shows an acid sensitive oligomeric acrylic ligand for metallic species.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

1. A method comprising:
forming a resist using a highly absorbing material;
thinning the resist to a pre-determined thickness used as an imaging layer; and
improving efficiency of a photoactive acid generator (PAG) to capture secondary electrons produced by an ionizing radiation in the resist.

2. The method of claim 1 wherein forming the resist comprises:
forming the resist using a highly absorbing material selected from fluorine (F), tin (Sn), bismuth (Bi), cesium (Cs), and antimony (Sb).

3. The method of claim 2 wherein forming the resist comprises:
adding at least one of the fluorine (F), tin (Sn), bismuth (Bi), cesium (Cs), and antimony (Sb) into a baseline material.

4. The method of claim 2 wherein forming the resist comprises:
forming the resist using one of a fluoropolymer, a metallocence polymer, an alkoxide chelate polymer, and a carboxylate chelate polymer.

5. The method of claim 1 wherein thinning comprises:
thinning the resist to a thickness below 100 nm.

6. The method of claim 1 wherein improving comprises:
increasing a PAG concentration in the resist.

7. The method of claim 1 wherein improving comprises:
controlling moieties proximal to a cleavable bond in the PAG.

8. The method of claim 1 further comprising:
exposing the resist with a radiation being one of an extreme ultraviolet (EUV), X-ray, electron beam, and ion beam.

9. A method comprising:
forming an imaging layer from a resist made of a highly absorbing material, the layer being thinned to a pre-determined thickness, the layer having improved efficiency of a photoactive acid generator (PAG) to capture secondary electrons produced by an ionizing radiation; and
forming an etch resistant layer below the imaging layer for pattern transfer from the imaging layer.

10. The method of claim 9 wherein the highly absorbing material is selected from fluorine (F), tin (Sn), bismuth (Bi), cesium (Cs), and antimony (Sb).

11. The method of claim 10 wherein forming the imaging layer comprises:
adding to a baseline material by at least one of the fluorine (F), tin (Sn), bismuth (Bi), cesium (Cs), and antimony (Sb).

12. The method of claim 10 wherein the imaging layer is made by one of a fluoropolymer, a metallocence polymer, an alkoxide chelate polymer, and a carboxylate chelate polymer.

13. The method of claim 9 wherein the thickness is below 100 nm.

14. The method of claim 9 wherein the imaging layer has an increased PAG concentration.

15. The method of claim 9 wherein the imaging layer has controlled moieties proximal to a cleavable bond in the PAG.

16. The method of claim 11 further comprising:
exposing the imaging layer to a radiation being one of an extreme ultraviolet (EUV), X-ray, electron beam, and ion beam.

17. A device comprising:
an imaging layer made of a highly absorbing material, the layer being thinned to a pre-determined thickness, the layer having improved efficiency of a photoactive acid generator (PAG) to capture secondary electrons produced by an ionizing radiation; and
an etch resistant layer below the imaging layer for pattern transfer from the imaging layer.

18. The device of claim 11 wherein the highly absorbing material is selected from fluorine (F), tin (Sn), bismuth (Bi), cesium (Cs), and antimony (Sb).

19. The device of claim 12 wherein the imaging layer comprises:
a baseline material added by at least one of the fluorine (F), tin (Sn), bismuth (Bi), cesium (Cs), and antimony (Sb).

20. The device of claim 12 wherein the imaging layer is made by one of a fluoropolymer, a metallocence polymer, an alkoxide chelate polymer, and a carboxylate chelate polymer.

21. The device of claim 11 wherein the thickness is below 100 nm.

22. The device of claim 11 wherein the imaging layer has an increased PAG concentration.

23. The device of claim 11 wherein the imaging layer has controlled moieties proximal to a cleavable bond in the PAG.

24. The device of claim 18 wherein the imaging layer is exposed with the radiation being one of an extreme ultraviolet (EUV), X-ray, electron beam, and ion beam.
